(19) United States
(12) Patent Application Publication
(10) Pub. No.: US 2024/0052474 A1
(43) Pub. Date: Feb. 15, 2024

(54) ORGANIC VAPOR JET PRINTING SYSTEM

(71) Applicant: Universal Display Corporation, Ewing, NJ (US)

(72) Inventors: William E. QUINN, Whitehouse Station, NJ (US); Gregory MCGRAW, Yardley, PA (US); Craig Anthony OUTTEN, Rydal, PA (US); Roman KOROTKOV, Cranbury, NJ (US); Seckin GOKALTUN, Dresher, PA (US)

(21) Appl. No.: 18/228,892

(22) Filed: Aug. 1, 2023

Related U.S. Application Data
(60) Provisional application No. 63/415,460, filed on Oct. 12, 2022.
(60) Provisional application No. 63/398,066, filed on Aug. 15, 2022.

(51) Int. Cl. C23C 14/04

(52) U.S. Cl. CPC C23C 14/04; H10K 71/135

(57) ABSTRACT

Devices suitable for use in OVJP and similar deposition techniques are provided that include multiple delivery apertures that are uncoupled from one another, allowing for more plateau-like deposition profiles. Fabrication techniques for such devices are also provided in which multiple wafers are etched and laminated to one another to form a monolithic depositor block.

### FIELD

The present invention relates to OVJP-type devices and techniques for fabricating organic emissive devices, such as organic light emitting diodes, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 I, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows example deposition profiles for conventional OVJP techniques in comparison to an ideal deposition profile.

FIG. 4A shows an example of a single-aperture OVJP print die as viewed from the substrate;

FIG. 4B shows a cross-sectional side view of the depositor of FIG. 4A; FIG. 4C shows an example deposition profile form single aperture OVJP print die.

FIG. 5A shows an example OVJP depositor having a split delivery aperture; FIG. 5B shows an example deposition profile for a depositor as shown in FIG. 5A.

FIG. 6A shows an example OVJP depositor having a bifurcated depositor; FIG. 6B shows an example deposition profile for a depositor as shown in FIG. 6A.

FIG. 7A shows an example OVJP depositor having a split delivery aperture with additional fill apertures; FIG. 7B shows an example simulated deposition profile for a depositor as shown in FIG. 7A; FIG. 7C shows an example experimental deposition profile for a depositor as shown in FIG. 7A.

FIG. 8A shows an OVJP depositor according to embodiments disclosed herein; FIG. 8B shows a linear array of depositors as shown in FIG. 8A; FIG. 8C shows example deposition profiles for a depositor as shown in FIG. 8A.

FIGS. 9A, 9B, and 9C show example depositors according to embodiments disclosed herein as shown in FIGS. 8A and 8B that include staggered delivery aperture arrangements.

FIG. 10 shows example deposition profiles for OVJP depositors as shown in FIGS. 9A-9C.

FIG. 11 shows OVJP depositor examples according to embodiments disclosed herein.

FIG. 12 shows OVJP depositor examples according to embodiments disclosed herein.

FIG. 13 shows OVJP depositor examples according to embodiments disclosed herein.

FIG. 14 shows OVJP depositor examples according to embodiments disclosed herein.

FIG. 15 shows OVJP depositor examples according to embodiments disclosed herein.

FIG. 16 shows OVJP depositor examples according to embodiments disclosed herein.

FIG. 17 shows OVJP depositor examples according to embodiments disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

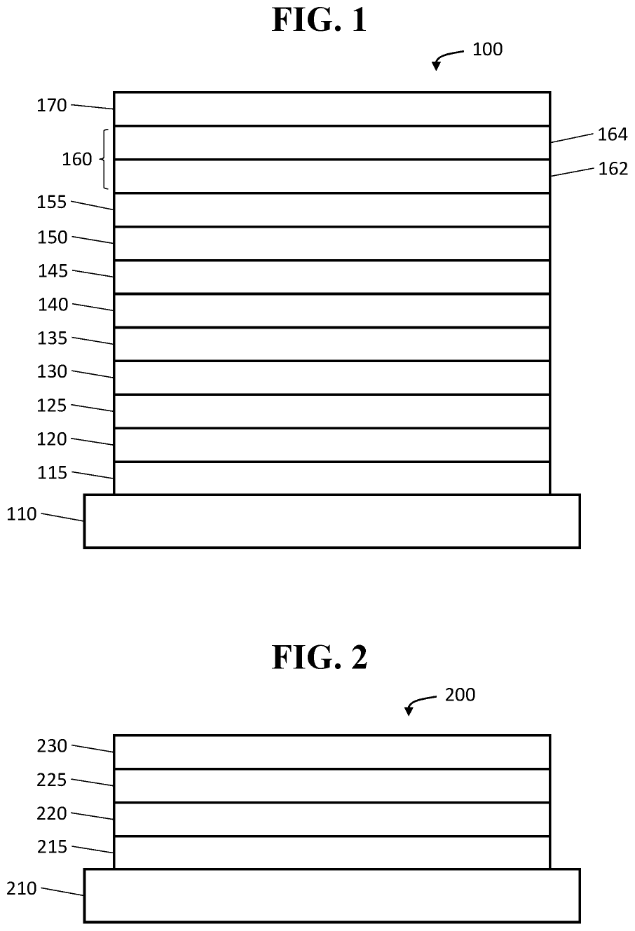

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, one type of technique for fabricating OLEDs and similar devices is OVJP, a maskless, solventless approach to printing large area OLED displays. In OVJP, narrow lines of OLED material are printed on the display backplane using a series of apertures formed in a silicon die, which may be manufactured using Microelectromechanical systems (MEMS) technology. Specific examples of OVJP systems are disclosed in U.S. Pat. Nos. 10,170,701 and 11,267,012, the disclosure of each of which is incorporated by reference in its entirety, and U.S. Application Publication Nos. 2019/0221783 and 2019/0218655, the disclosure of each of which is incorporated by reference in its entirety.

When OVJP systems and techniques are used to fabricate OLEDs and similar devices, OLED material is printed over columns of anodes which are separated by thin lines of insulating material. To maximize display performance the ratio of anode area to pixel separation area is maximized. This requires the OVJP print profile to approximate a square wave profile; the profile must have steep sidewalls and a flat top between the sidewalls. Computational flow dynamics (CFD) modeling of the deposition profile often is used to aid in the design of the apertures. CFD-modeled aperture designs can produce deposition profiles with steep sidewalls or flat tops. However, as described in further detail herein, it has been found that when such designs are combined in a single mirror symmetric die, the actual deposition profile may deviate considerably from the predicted profile. CFD loses predictive power when evaluating depositors with very small features. Print die geometries disclosed herein permit the printing of profiles having steep sidewalls and a flat top using print apertures of moderate size. Additionally, depositor arrangements disclosed herein provide fully decoupled depositors as well as combinations of such decoupled depositors in a fully functional printing array.

In contrast to other deposition techniques, such as organic vapor phase deposition (OVPD), chemical vapor deposition (CVD), atomic layer deposition (ALD), and the like which are designed to deposit blanket layers of material over a substrate, OVJP techniques deposit narrow lines of organic material on a substrate without the use of a shadow mask, fine metal mask, or equivalent device.

Conventional devices and techniques employed to produce displays such as mobile phone and laptop displays often use evaporation sources and fine metal masks to pattern the deposition, for example as are common with non-OVJP deposition techniques. Fine metal masks are typically not suitable for use in manufacturing large area displays because the masks cannot be stretched with sufficient force to prevent sagging. Inkjet printing is a potential patterning technique for Organic Light Emitting Diode (OLED) displays, but the use of solvents to make the inks seriously degrades the performance of the light emitting devices. OVJP eliminates these two issues by printing lines having pixel width without the use of fine metal masks. Notably, OVJP uses state-of-the-art OLED materials without dissolving them in a solvent.

In OVJP, OLED materials are heated in an enclosed container to an elevated sublimation temperature and transported to a printhead through heated gas lines using an inert carrier gas. The printhead contains jetting apertures with a spacing that corresponds to the pixel pitch of the display. Apertures are formed in silicon wafers using standard micro-electromechanical systems (MEMS) fabrication techniques. Functional OVJP dies are cut from the wafer, with the apertures located along one face of the die. Excess organic material is removed from the printing area by vacuum channels inserted into the print die. The aperture face of the die is held above a moving display backplane, and lines corresponding to the pixels are printed on the backplane.

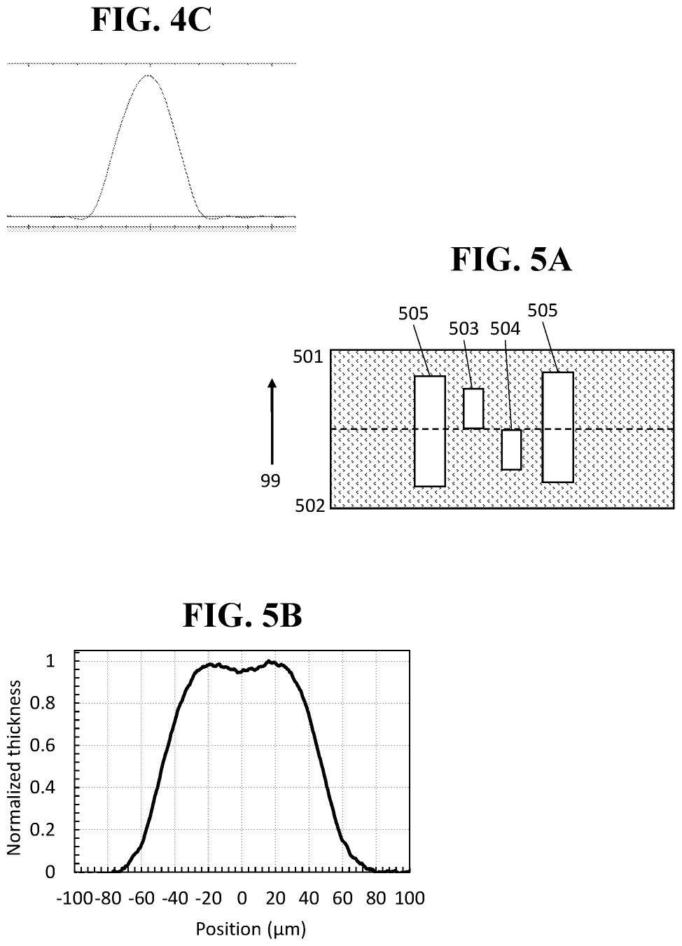

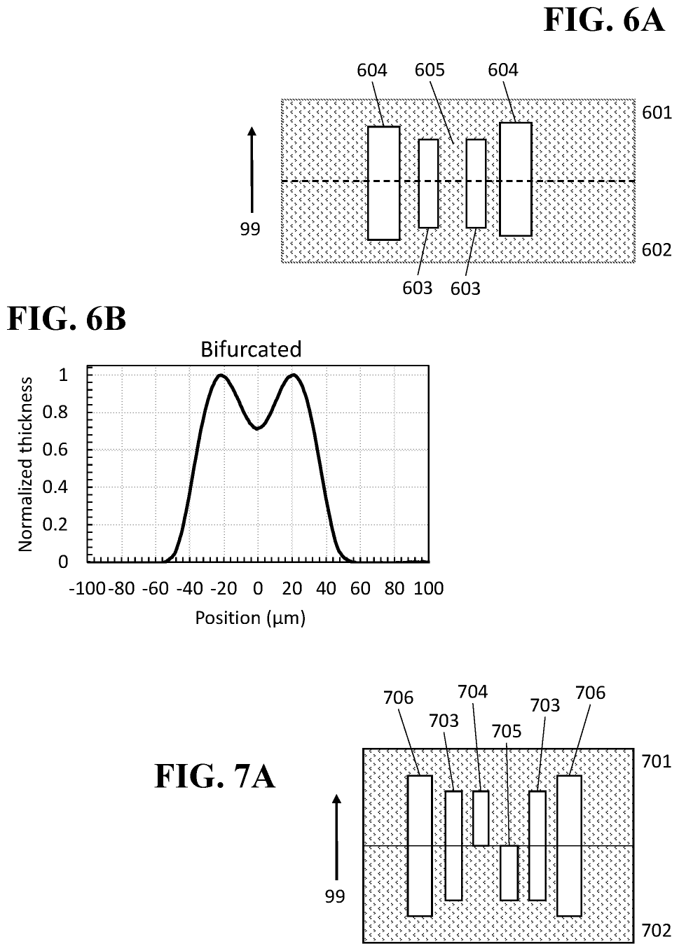

MEMS fabrication techniques can be used to fabricate OVJP depositors by defining channels and apertures in the faces of a number of wafers and bonding the wafers together. The features are arranged so that the die halves are mirror images with the exhaust apertures aligning and the deposition apertures can be aligned or offset. For example, FIGS. 4A and 6A show examples of aperture designs in which the bonded half die has aligned deposition apertures. FIG. 5 shows an example design having mirror-image deposition apertures. After bonding two wafers, wafer pairs may be sawn into die such that the deposition and exhaust apertures along one edge of each die are exposed. One of the wafers has through wafer vias that connect the gas channels to the outside of the wafer. The vias are connected to the deposition gas and vacuum sources by a physical seal such as a flat surface seal or an O-ring, or by bonding the die to a manifold. This type of die uses gas convection to print narrow, well-defined lines on a substrate that is translated below the aperture face of the die.

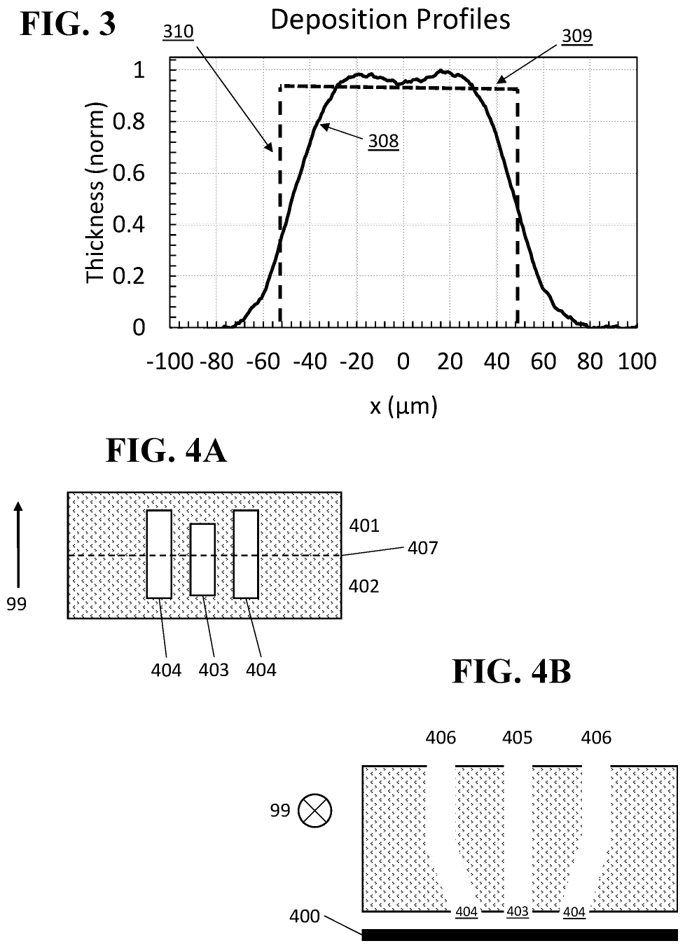

FIG. 3 shows an example of an ideal deposition profile compared to a simulation of an actual deposition profile for an illustrative conventional OVJP depositor. There are two important features of the deposition profile, i.e., the thickness line profile transverse to the direction of printing: a preferably flat top, shown in the dotted line profile 309 in FIG. 3; and steep sidewalls, shown as the profile side edges 310 in FIG. 3. An ideal profile is a square wave as shown by 309 and 310. An example of an actual deposition profile 308 is also provided for comparison; notably the top of the deposited material is largely not flat and the side walls flare out at the base and narrow at the top. The thickness profile of actual features may be optimized by changing the size and positions of the delivery and exhaust apertures of the print die. Notably, the profile of material deposited by an OVJP depositor may be largely or entirely controlled by the shape and arrangement of depositor apertures, including delivery and exhaust apertures, such that a range of operational parameters of the system will produce the desired profile (though they may be relevant for other features of the deposition).

An example of an OVJP depositor with a single delivery aperture is shown in FIGS. 4A-4B. FIG. 4A shows the depositor face-on as it would appear from the substrate surface, which may be positioned above or below the depositor, with a surface of the substrate on which material is to be deposited arranged toward the depositor. The delivery aperture 403 is flanked by two exhaust apertures 404. The die is fabricated from two Si wafers 401 and 402, with shaded/stippled areas indicating regions of solid wafer material and unshaded areas indicating apertures on the edge of the die. The midline of the depositor 407 corresponds to the joint formed between the two halves of the die by wafer bonding as previously disclosed. The apertures are formed by etching channels into the faces of two wafers 401, 402 and bonding the two wafers together. The direction of relative motion of the depositor in relation to a substrate on which material is to be deposited is shown by the arrow 99, which is used throughout the drawings to indicate the same.

FIG. 4B shows a cross-sectional view of the channels within a die and normal to the scan direction of printing, arranged above the substrate 400. The delivery and exhaust apertures 403, 404, respectively in FIG. 4A are formed by terminating delivery 405 and exhaust 406 channels etched into each wafer at the lower edge of the die to form an aperture array. Single delivery aperture depositors produce a Gaussian-like profile as shown in FIG. 4C. This profile is not appropriate for use in an OLED display; the thickness of the emissive material over the anode must be uniform to achieve good device properties and lifetime.

A profile with a much more uniform flat top can be obtained using a die design as shown in FIG. 5A. The depositors use the same basic layout as before, formed from two wafers 501, 502 as previously disclosed. The delivery aperture is split into two offset sections 503, 504, which are not arranged symmetrically around any axis of motion of the depositor, i.e., an axis parallel to the direction of motion 99. As previously disclosed, the depositor may be formed by etching appropriate channels into two wafers 501, 502 that are subsequently bonded together into a single monolithic block. This design has two delivery apertures 503, 504 which are spaced at different distances from each of the exhaust apertures 505. This configuration provides a flat top profile as shown in FIG. 5B; however, the profile does not have steep sidewalls. Steep sidewall profiles are desired to minimize the space between neighboring pixels and maximize the ratio of emitting to non-emitting areas in the display. Increasing the ratio of emitting to non-emitting area improves display brightness and lifetime. An example of such a depositor is disclosed in U.S. Application Pub. No. 2019/0218655, the disclosure of which is incorporated by reference in its entirety.

FIG. 6A shows another delivery/exhaust arrangement in which the delivery aperture 603 is bifurcated lengthwise by a silicon septum 605 into two identical delivery apertures 603 positioned between the exhaust apertures 604. In this example, the two portions of the delivery aperture are symmetric and uniform with respect to an axis between them (through the septum 605) that is parallel to the direction of relative motion 99 of the depositor and the substrate.

The depositor shown in FIG. 6A results in a deposition profile having relatively narrow sidewalls as shown in FIG. 6B. However, the area between the sidewalls has a deep dip which is not appropriate for display printing. Nonuniform thickness in the pixel area negatively affects light emitting device performance and lifetime.

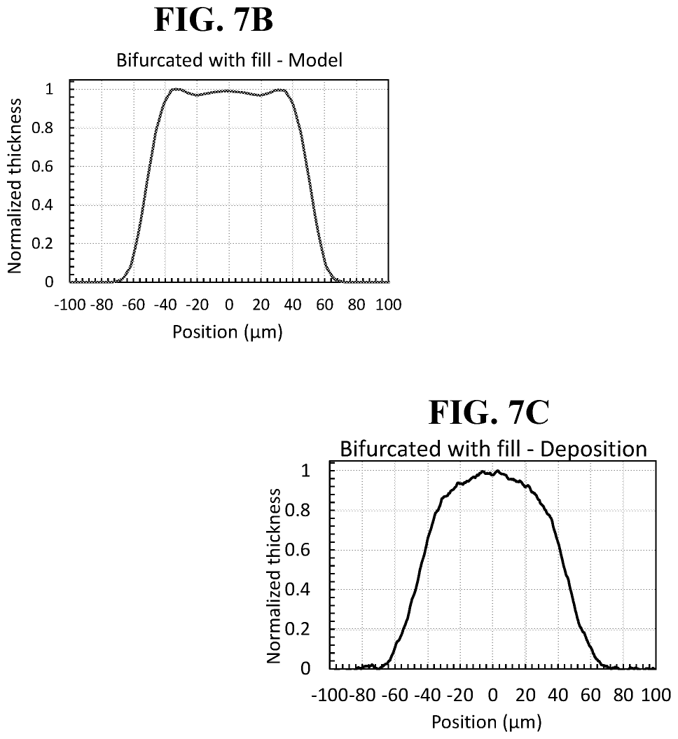

FIG. 7A shows a depositor that combines aperture features from the designs shown in FIGS. 5A and 6A. This design includes outer exhaust apertures 706, two symmetric delivery apertures 703, and two non-symmetric inner delivery apertures 704, 705. The depositor may be formed from two wafers 701, 702 combined to form a monolithic block as previously disclosed. Modeling predicted that the print profile of this depositor would have the shape shown in FIG. 7B—a profile with relatively steep sidewalls and flat top. However, actual deposition results from a die manufactured according to this design did not confirm the modeling prediction, instead resulting in the deposition profile shown in FIG. 7C. Thus it has been found that placing deposition apertures close to each other does not produce individual peaks in the deposition profile as predicted and shown in FIG. 7B, but rather a single Gaussian-like peak at the center of mass of the apertures as shown in FIG. 7C. This is an unexpected result that was not predicted by the CFD models. The conclusion from this testing is that coupling of deposition apertures. Process gas flow from the inner delivery apertures interferes with deposition from the symmetric delivery apertures in a manner that may be difficult to anticipate. It is therefore desirable to use a depositor arrangement that decouples the delivery apertures and avoid arrangements where the separation between deposition channels is less than about 5-15 μm.

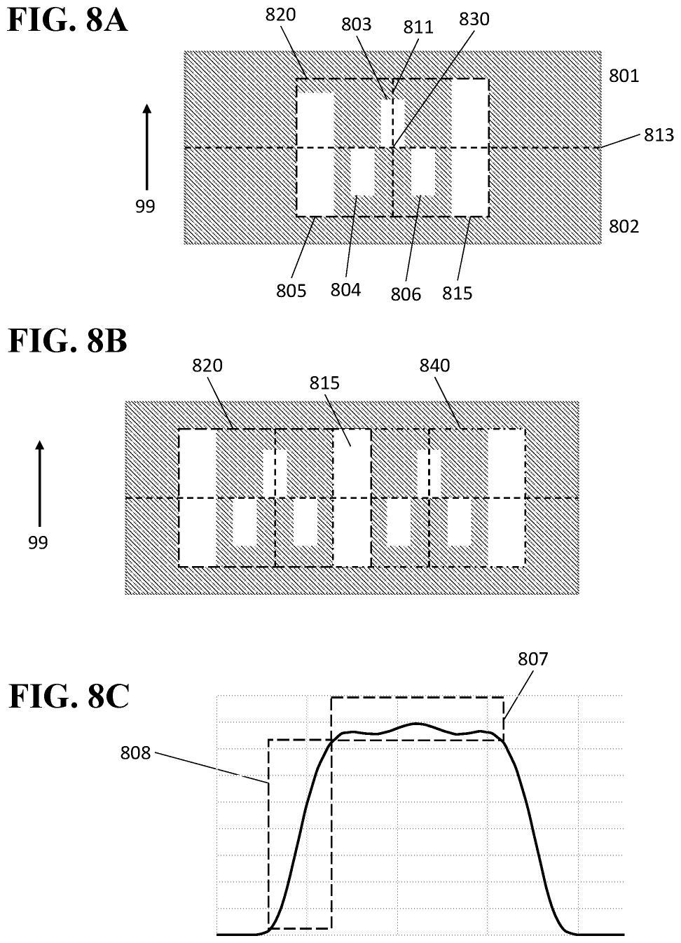

To overcome the coupling effect that occurs with closely spaced deposition apertures, a novel design and associated manufacture of an OVJP die is provided herein. The die is made by bonding two wafers 801, 802 with etched channels together. However, unlike many prior arrangements, the wafers do not have mirror symmetry or similar exhaust to delivery aperture spacing. FIG. 8A shows a preferred embodiment of the design, again as viewed from a substrate positioned for deposition, with the relative direction of motion of the depositor relative to the substrate shown at 99. The depositor includes a pair of delivery apertures 804, 806 etched into one side of the Si die containing the micronozzle array and a single delivery aperture 803 etched into the other side, all disposed between exhaust apertures 805, 815. The depositor may include only these three delivery apertures, i.e., there may be no other delivery apertures between the exhaust apertures 805, 815. For such an arrangement, it may be convenient to refer to a region defined by the outer edges of the exhaust apertures 820. Each side of this region is defined by the outermost edge of the exhaust aperture that is farthest from the center 830 of the depositor. The exhaust apertures 805, 815 typically will be of uniform shape and size, but if non-uniform exhaust apertures are used, the region 820 may be defined by the outermost edge of either depositor. For example, as shown in FIG. 8A, the top edge of the region defined by the exhaust apertures is defined by the top edge of the right aperture 815, which extends farther than the top edge of the left aperture 805. Similarly, the left and right edges of the region are defined by the outermost edges of each exhaust aperture. In this depositor configuration, the delivery apertures 803, 804, 806 are the only delivery apertures within the region defined by the outer edges of the exhaust apertures. Based on the tests and results previously disclosed herein, the delivery apertures 803, 804, 806 may be separated from one another in a direction along the center line 813 by 5 μm, 10 μm, 15 μm, or any intervening distance. The delivery aperture 803 may be separated from the delivery apertures 804, 806 along the axis 811 by 0-20 μm. In this context, a separation of 0 μm indicates that the “top” edge of the depositor 804 or 806 and the “bottom” edge of the depositor 803 (relative to the page) lie on the same line, such as the axis 813. The separation along the axis 813 between the apertures 803 and 804/806 may still be any value disclosed herein, such as 5-15 μm. That is, the distance between delivery apertures along the two axes 811, 813 may be selected independently of one another.

The region defined by the outer edges of the exhaust apertures also may be used as a convenient definition of the “depositor” as disclosed herein. That is, a single depositor can be described as including all the apertures within the region 820. In depositor arrays where adjacent depositors share a common exhaust aperture, the associated regions may be defined by the shared exhaust aperture. For example, FIG. 8B shows an array that includes two depositors 820, 840 as defined above. The depositors share a common exhaust aperture 815, which defines the rightmost edge of depositor 820 and the leftmost edge of depositor 840. Similar to the arrangement shown in FIG. 8A, in each depositor 820, 840 there are no exhaust apertures and no delivery apertures other than the three previously described within the regions 820, 840 defined by each pair of exhaust apertures.

Referring again to FIG. 8A, the depositor includes two delivery apertures 804, 806 that are symmetrically arranged between the exhaust apertures 805, 815 with respect to an axis of the depositor 811 which is parallel to the major axes of the exhaust apertures 805, 815. However, as previously disclosed, the exhaust apertures 803, 804, 806 are not symmetric about the orthogonal axis 813 defined by the interface between the two wafers 801, 802. Specifically, the region directly across the wafer interface 813 from the single delivery aperture 803 does not include any delivery apertures.

If operated alone, the pair of delivery apertures 804, 806 generate a deposition profile with sharp sidewalls but poor center fill, similar to the example shown in FIG. 6B. Similarly, the single center delivery aperture 803 can be expected to generate a roughly Gaussian profile like the example shown in FIG. 4C. Deposition from these two features add to generate a deposition profile that approximates the square-wave ideal profile much more closely than other depositor geometries. An expected deposition profile for a depositor of this design generated by CFD is shown in FIG. 8C. The profile retains the sharp sidewalls 808 generated paired delivery apertures, and the center delivery aperture fills in the central portion of the deposition profile 807, so that the region around the midline of the printed feature is relatively uniform in thickness. Separating the single and double apertures decouples the functions of shaping the edge of a feature and filling in its center. This allows each aperture to be optimized separately and prevents the apertures from interacting with each other.

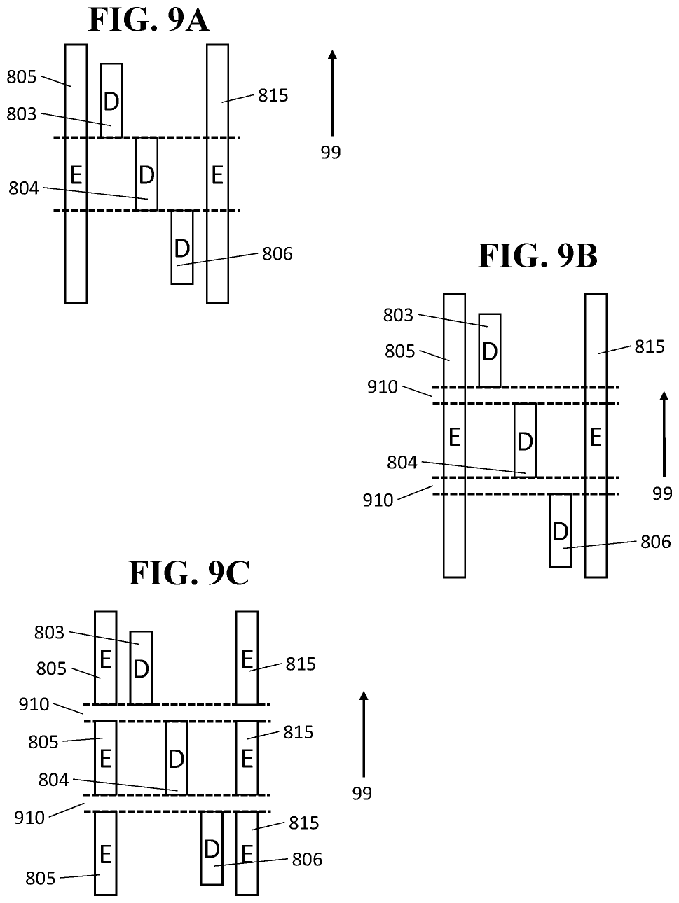

FIGS. 9A-9C show arrangements of delivery and exhaust apertures according to embodiments similar to those shown in FIGS. 8A and 8B, but where the delivery apertures are not symmetric about the axis in the direction of motion, such as axis 811 in FIG. 8A.

FIG. 9A shows a design with a set of decoupled deposition apertures transverse to the printing direction 99 with no gaps in the printing direction and no gaps in the exhaust apertures. The dashed lines represent bond lines where wafers are bonded together after individually etching the delivery and exhaust channels in the wafers as previously disclosed. As previously disclosed, the delivery apertures 803, 804, 806 may be separated from one another by 5-15 μm in a direction perpendicular to the direction of motion 99, i.e., perpendicular to the major axes of the exhaust apertures. FIG. 9A shows an arrangement in which the delivery apertures have approximately 0 μm spacing in the direction of motion 99. FIG. 9B shows a similar arrangement but with a separation 910 of up to 20 μm in the direction of motion 99 between delivery apertures 803, 804 and between delivery apertures 804, 806. FIG. 9C shows a similar arrangement in which the exhaust apertures have gaps of greater than 0 to 20 μm in the printing direction 99, matching the separation of delivery apertures in the same direction. In such an arrangement, each divided portion of the exhaust aperture 805, 815 may be connected to separate exhaust channels within the monolithic depositor block, or the three sections of each exhaust aperture may be connected to a single common exhaust channel in the depositor block, or two segments of each exhaust aperture may be connected to a common exhaust channel with the third segment connected to a separate channel. In some arrangements, it is believed that a greater deposition efficiency may be achieved by using a separate exhaust channel and vacuum source for the middle exhaust aperture and a common channel for the leading and trailing portions of each exhaust aperture.

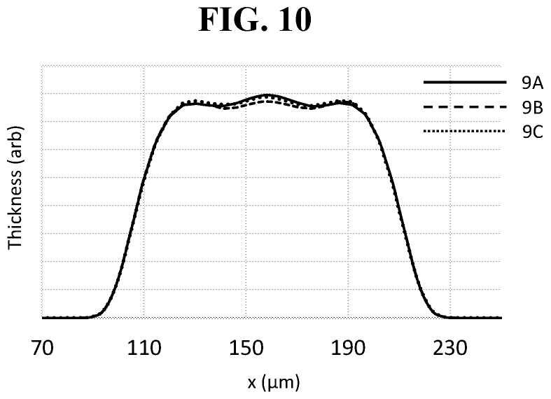

FIG. 10 shows a plot of modeled deposition profiles obtained with CFD for the aperture arrangements shown in FIGS. 9A-9C. Sidewall profiles of the designs are similar with minor variation in sidewall slope as shown Table 1. The flat top fill portions of the profiles show minor differences in the profiles. In both the sidewall and fill portions, the differences are minor indicating that separating deposition apertures in the direction of printing has little impact on the modeled print profile.

TABLE 1

| | FW5M | Slope | | |
|---|---|---|---|---|
| Design | (μm) | (%/μm) | UW (μm) | Sidewall (μm) |
| 9A | 126.69 | 3.63 | 77.25 | 20.39 |
| 9B | 126.97 | 3.95 | 77.25 | 20.20 |
| 9C | 126.87 | 3.73 | 77.25 | 20.21 |

The various depositors disclosed herein may be fabricated by etching the described channels and apertures in one or more wafers, then bonding the wafers to one another to achieve the described arrangement of apertures. As part of the bonding process, the matching delivery and/or exhaust apertures and channels in each wafer may be aligned or offset to achieve the desired arrangement of apertures. For example, referring to the arrangement shown in FIG. 8A, apertures 805, 803, 815 and corresponding channels may be etched into a first wafer 801, and apertures 805, 804, 806, 815 etched into a second wafer. The wafers are then aligned such that the exhaust channels align and the delivery aperture 803 does not align with either delivery aperture 804, 806, to achieve the arrangement shown. Once bonded, the wafers may form a single monolithic block, for example where the wafers and block are formed from Silicon or similar materials. For arrangements as shown in FIGS. 9A-9C, three wafers may be used, with the corresponding channels etched in each wafer. A similar alignment process may be used to create the exhaust channels and apertures and delivery channels and apertures as shown and described. The alignment and separation of channels in the wafers may follow the placement described with respect to the apertures, at least in the immediate region of the apertures. For example, delivery channels in a depositor block may be separated by 5-15 μm or 0-20 μm as disclosed with respect to the delivery apertures, at least in the region of the block immediately adjacent to the apertures.

Various dimensions may be used for the delivery and exhaust apertures disclosed herein. When used in OVJP deposition techniques, such as to fabricate OLEDs and similar devices, it generally is desirable for the apertures to be on the order of the features being deposited. For example, delivery apertures typically are rectangular, with a major axis (parallel to the direction of motion relative to the substrate) of about 300 micrometers and minor axis of 15 micrometers; exhaust apertures typically are rectangular with major axis of 300 to 500 micrometers and minor axis of 25 micrometers.

In contrast to depositors used in other deposition techniques, especially those that are designed to deposit blanket layers over relatively large areas of a substrate, OVJP depositors as disclosed herein typically require flow of material to be from the delivery apertures to the associated exhaust apertures in the same depositor. For example, referring to FIG. 8A, material ejected by the delivery apertures 803, 804, 806 typically will either deposit on the substrate or be removed via the exhaust apertures 805, 815, as opposed to exhaust apertures in other depositors in the same block. As used herein, such flow-connected apertures may be described as being “fluidly output-coupled” to one another. In an embodiment, fluidly output-coupled apertures may allow for 90-99% or more of the material ejected by the delivery aperture(s) to be either deposited on the substrate or removed via the coupled exhaust aperture(s). In a preferred embodiment, fluidly output-coupled apertures may allow for 98% or more of the material ejected by the delivery aperture(s) to be either deposited on the substrate or removed via the coupled exhaust aperture(s). Fluidly output-coupled flow as disclosed herein may be achieved by the size, relative placement, and shapes of the depositor apertures, and generally are not affected by changes in other operational parameters within ranges typical for OVJP deposition. In contrast, showerhead-type depositors and other depositors used in ALD, CVD, and similar deposition techniques, even if operated with OVJP-type materials, substrates, and depositor movement, typically cannot achieve the narrow, plateau-shaped depositions characteristic of OVJP. As a result, such depositors are unsuitable for use in OVJP applications.

As previously disclosed with respect to FIG. 8B, depositors as disclosed herein may be arranged in a linear or two-dimensional array on the substrate-facing side of the depositor block. In some such arrangements, adjacent depositors may have separate exhaust apertures and channels and/or they may share common exhaust apertures as shown in FIG. 8B. Depositor blocks having such arrays may be arranged in any desired size with any number of depositors. For example, a depositor block of 150 mm length containing 384 individual deposition apertures may be useful for fabricating large flat-panel displays and the like, whereas a depositor block of 100 mm containing 860 or more individual deposition apertures may be used for fabricating smaller displays, such as for use in portable devices such tablets or computer monitors. Regardless of the panel or substrate size, typically individual depositors may have varying sizes, that match the pixel pitch of the display and with aperture sizes as previously disclosed. As an example, for a 55″, 4K resolution display, the pixel pitch is 0.317 mm.

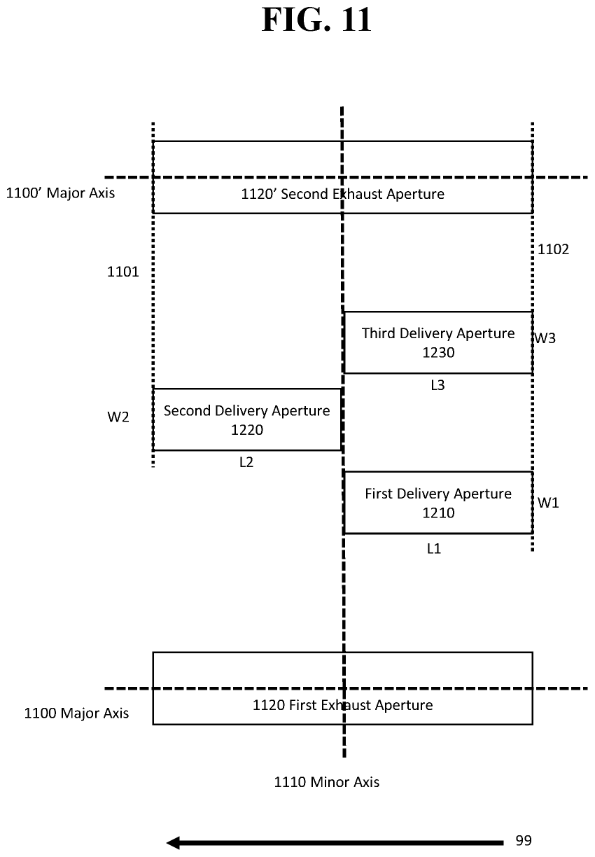

FIGS. 11-17 show OVJP depositor (i.e. deposition block) examples according to embodiments disclosed herein. It should be noted, FIGS. 11-17 show example OVJP depositor arrangements including a first delivery aperture 1210, second delivery aperture 1220, and third delivery aperture 1230 between a first exhaust aperture 1120 and a second exhaust aperture 1120′. In some embodiments, as described above, any number of delivery apertures may be located between the first exhaust aperture and second exhaust aperture. In such embodiments, the delivery apertures may overlap in any combination (i.e., in the direction of relative motion 99 and/or perpendicular to the direction of relative motion 99), as discussed further below. In an embodiment, the OVJP depositor may be formed as a deposition block from one, two, three, or more wafers. In some embodiments, the any number of delivery apertures may be located between any number of exhaust aperture.

As shown in FIGS. 11-17, the OVJP depositors and/or substrate move in a direction of relative motion 99. In an embodiment, the OVJP depositors include a first exhaust aperture 1120 and a second exhaust aperture 1120′. In an embodiment, the first exhaust aperture 1120 and the second exhaust aperture 1120′ include a major axis 1100 and major axis 1100′, respectively, and the major axis is parallel to the direction of relative motion 99. In an embodiment, the first exhaust aperture 1120 and the second exhaust aperture 1120′ include a minor axis 1110 that extends in a direction perpendicular to the direction of relative motion 99. In an embodiment, the first exhaust aperture 1120 may be substantially similar in size to second exhaust aperture 1120′. In an alternative embodiment, the first exhaust aperture 1120 may have a first length along the major axis 1100 and the second exhaust aperture 1120′ may have a second length along the major axis 1100′ but they both have a same size along the minor axis for each of the first exhaust aperture 1120 and second exhaust aperture 1120′. In an alternative embodiment, the first exhaust aperture 1120 may have a first length along the minor axis and the second exhaust aperture 1120′ may have a second length along the minor axis 1120 but they both have a same size along the major axis 1100 of the first exhaust aperture 1120 and the major axis 1100′ of the second exhaust aperture 1120′. In yet another alternative embodiment, the first exhaust aperture 1120 and the second exhaust aperture 1120′ may have different lengths in both the major axis 1100/1100′ and minor axis 1110. In an embodiment, the first exhaust aperture 1120 and second exhaust aperture 1120′ may range in size from 0.5 mm to 1 mm along the major axis 1100/1100′. In an embodiment, the first exhaust aperture 1120 and second exhaust aperture 1120″ may range in size from 0.01 mm to 0.1 mm along the minor axis 1110. In an embodiment, one or both of the major axis 1100 of the first exhaust aperture 1120 and the major axis 1100′ of the second exhaust aperture 1120′ may be larger or smaller than the minor axis 1110 of one or both of the first exhaust aperture 1120 and the second exhaust aperture 1120′.

In an embodiment, as shown in FIGS. 11-17, OVJP depositor examples include a first delivery aperture 1210, a second delivery apertures 1220, and a third delivery aperture 1230. In an embodiment, the first delivery aperture 1210 has a first length and first width. In an embodiment, the first length may be larger, substantially similar, or smaller than the first width. In an embodiment, the second delivery aperture 1220 has a second length and second width. In an embodiment, the second length may be larger, substantially similar, or smaller than the second width. In an embodiment, the third delivery aperture 1230 has a third length and third width. In an embodiment, the third length may be larger, substantially similar, or smaller than the third width. In an embodiment, the first length, second length, and/or third length may be larger, substantially the same, or smaller than any of the other lengths of any of the delivery apertures. In an embodiment, the first width, second width, and/or third width may be larger, substantially the same, or smaller than any of the other widths of any of the delivery apertures. In an embodiment, the width and length of the delivery apertures may range from 0.01 mm to 1 mm. As discussed above, the OVJP depositor can include any number of delivery apertures and therefore may have any number of delivery aperture lengths and delivery aperture widths.

In an embodiment, as shown in some of FIGS. 11-17, the term “top” or “leading” edge is used to describe an edge of either a delivery aperture or an exhaust aperture in the direction of relative motion 99 the OVJP depositor/substrate is going and the term “bottom” or “trailing” edge is used to describe an edge of either a delivery aperture or an exhaust aperture in the direction of relative motion 99 the OVJP depositor/substrate has already been. That is, during operation of the depositor, for a given fixed point in space, the top or leading edge will pass the fixed point before the bottom or trailing edge. In an embodiment, a “top” edge of one or more of the delivery apertures may align, along an axis parallel to the minor axis, with the “top” edge of one or more of the first exhaust aperture 1120 and second exhaust aperture 1120′. In an embodiment, a “bottom” edge of one or more of the delivery apertures may align, along an axis parallel to the minor axis, with the “bottom” edge of one or more of the first exhaust aperture 1120 and second exhaust aperture 1120′. In an embodiment, “align” means no space is between the two edges along an axis parallel to the minor axis. In an alternative embodiment, a “top” edge of one or more of the delivery apertures may be 0-20 μm in either direction, along an axis parallel to the minor axis, from the “top” edge of one or more of the first exhaust aperture 1120 and second exhaust aperture 1120′. In an embodiment, a “bottom” edge of one or more of the delivery apertures may be 0-20 μm in either direction, along an axis parallel to the minor axis, from the “bottom” edge of one or more of the first exhaust aperture 1120 and second exhaust aperture 1120′.

In an embodiment, as shown in some of FIGS. 11-17, the term “side” edge is used to describe a side of either a delivery aperture or an exhaust aperture perpendicular to the direction of relative motion 99. In an embodiment, one or both “side” edges of the first delivery aperture 1210, second delivery aperture 1220, and/or third delivery aperture may align, along an axis parallel to the major axis, with a “side” edge of the first exhaust aperture 1120, a “side” edge of the second exhaust aperture 1120′, or a “side” edge of any other delivery aperture. In an alternative embodiment, one or both “side” edges of the first delivery aperture 1210, second delivery aperture 1220, and/or third delivery aperture may be 0-20 μm in either direction, along an axis parallel to the major axis, from a “side” edge of the first exhaust aperture 1120, a “side” edge of the second exhaust aperture 1120′, or a “side” edge of any other delivery aperture.

In an embodiment, as shown in some of FIGS. 11-17, a “top” edge of one or more of the first delivery aperture 1210, second delivery aperture 1220, or third delivery aperture 1230 may align, along an axis parallel to the minor axis 1110, with a “bottom” edge of one or more of the first delivery aperture 1210, second delivery aperture 1220, or third delivery aperture 1230. In an alternative embodiment, a “top” edge of one or more of the first delivery aperture 1210, second delivery aperture 1220, or third delivery aperture 1230 may be 0-20 μm in either direction (i.e. a space or overlap), along an axis parallel to the minor axis 1110, with a “bottom” edge of one or more of the first delivery aperture 1210, second delivery aperture 1220, or third delivery aperture 1230.

In an embodiment, as shown in some of FIGS. 11-17, a “side” edge of one or more of the first delivery aperture 1210, second delivery aperture 1220, or third delivery aperture 1230 may align, along an axis parallel to the major axis 1100, 1100′, with a “side” edge of one or more of the first delivery aperture 1210, second delivery aperture 1220, or third delivery aperture 1230. In an alternative embodiment, a “side” edge of one or more of the first delivery aperture 1210, second delivery aperture 1220, or third delivery aperture 1230 may be 0-20 μm in either direction (i.e. a space or overlap), along an axis parallel to the major axis 1100,1100′, with a “side” edge of one or more of the first delivery aperture 1210, second delivery aperture 1220, or third delivery aperture 1230.

In a first example, as shown in FIG. 11, a “top” edge of the second delivery aperture 1220 aligns with the “top” edge of the first exhaust aperture 1120 and second exhaust aperture 1120′ along an axis 1101 parallel to the minor axis 1110. Here, the “bottom” edge of the first delivery aperture 1210 and “bottom” edge of the third delivery aperture 1230 align with the “bottom” edge of the first exhaust aperture 1120 and second exhaust aperture 1120′ along an axis 1102 parallel to the minor axis 1110. In this example, the “top” edge of the first delivery aperture 1210 and the “top” edge of the third delivery aperture 1230 align with the “bottom” edge of the second delivery aperture 1220 along an axis parallel to and coincident with the minor axis 1110. In this example, the “top” and “bottom” of the first delivery aperture 1210 and third delivery aperture 1230 are aligned along an axis parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100, 1100′.

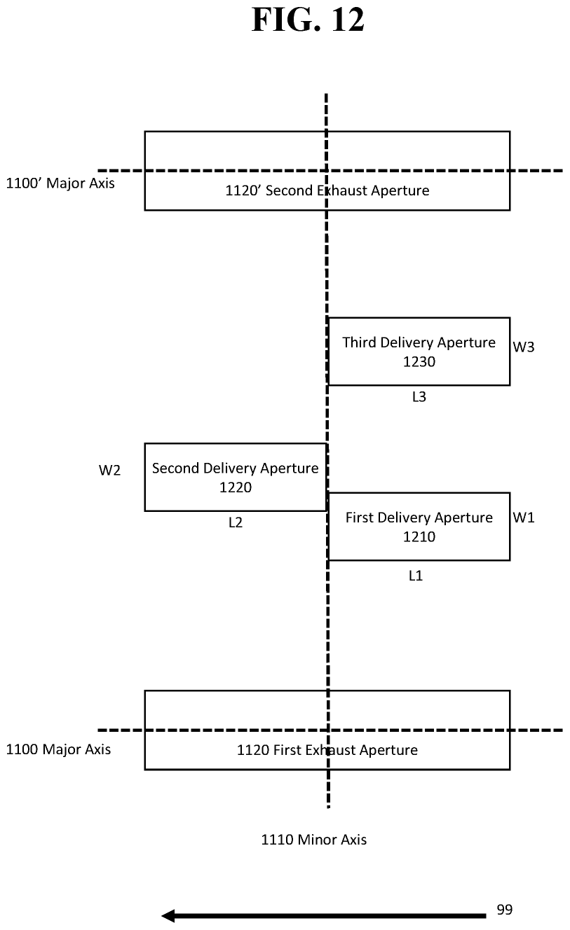

In a second example, as shown in FIG. 12, a “top” edge of the second delivery aperture 1220 aligns with the “top” edge of the first exhaust aperture 1120 and second exhaust aperture 1120′ along an axis parallel to the minor axis 1110. Here, the “bottom” edge of the first delivery aperture 1210 and “bottom” edge of the third delivery aperture 1230 align with the “bottom” edge of the first exhaust aperture 1120 and second exhaust aperture 1120′ along an axis parallel to the minor axis 1110. In this example, the “top” edge of the first delivery aperture 1210 and the “top” edge of the third delivery aperture 1230 align with the “bottom” edge of the second delivery aperture 1220 along an axis parallel to the minor axis 1110. In this example, the “top” and “bottom” of the first delivery aperture 1210 and third delivery aperture 1230 are aligned along an axis parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100,1100′ with the exception of a “side” of the first delivery aperture 1210 and second delivery aperture 1220. Here, a “side” of the first delivery aperture 1210 overlaps, on an axis parallel to the major axis 1100, 1100′, with a “side” of the second delivery aperture 1220.

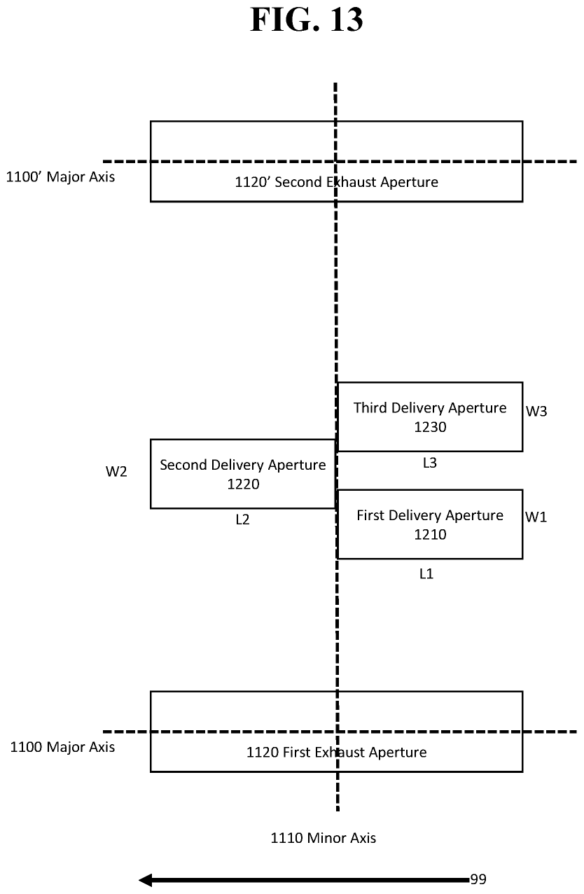

In a third example, as shown in FIG. 13, a “top” edge of the second delivery aperture 1220 aligns with the “top” edge of the first exhaust aperture 1120 and second exhaust aperture 1120′ along an axis parallel to the minor axis 1110. Here, the “bottom” edge of the first delivery aperture 1210 and “bottom” edge of the third delivery aperture 1230 align with the “bottom” edge of the first exhaust aperture 1120 and second exhaust aperture 1120′ along an axis parallel to the minor axis 1110. In this example, the “top” edge of the first delivery aperture 1210 and the “top” edge of the third delivery aperture 1230 align with the “bottom” edge of the second delivery aperture 1220 along an axis parallel to the minor axis 1110. In this example, the “top” and “bottom” of the first delivery aperture 1210 and third delivery aperture 1230 are aligned along an axis parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100,1100′ with the exception of a “side” of the first delivery aperture 1210, second delivery aperture 1220 and third delivery aperture 1230. Here, a “side” of the first delivery aperture 1210 overlaps, on an axis parallel to the major axis 1100,1100′, with a “side” of the second delivery aperture 1220 and a “side” of the second delivery aperture 1220 overlaps with a, on an axis parallel to the major axis 1100, 1100′, with a “side” of the third delivery aperture 1230.

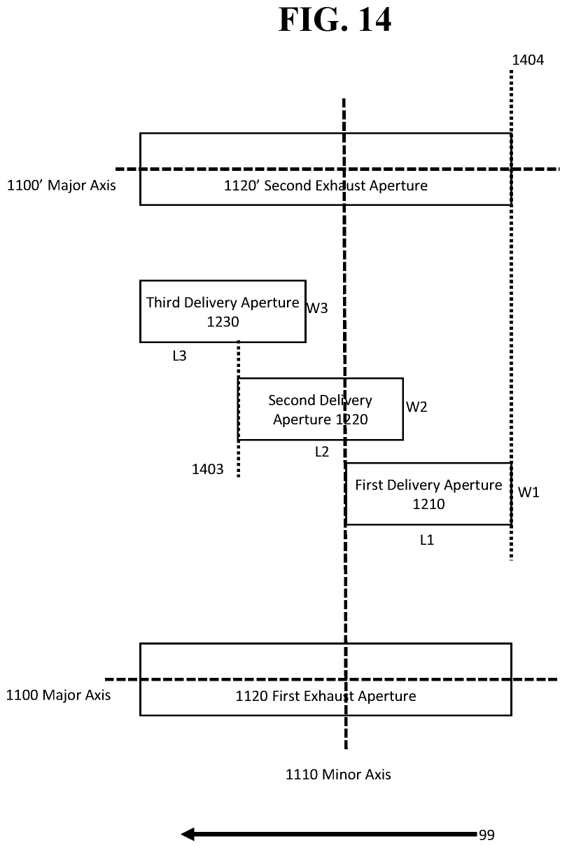

In a fourth example, as shown in FIG. 14, a “top” edge of the third delivery aperture 1230 aligns with the “top” edge of the first exhaust aperture 1120 and second exhaust aperture 1120′ along an axis parallel to the minor axis 1110. Here, the “bottom” edge of the first delivery aperture 1210 align with the “bottom” edge of the first exhaust aperture 1120 and second exhaust aperture 1120′ along an axis 1404 parallel to the minor axis 1110. In this example, the “top” edge of the first delivery aperture 1210 overlaps with the “bottom” edge of the second delivery aperture 1220 along an axis parallel to the minor axis 1110. In this example, the “top” edge of the second delivery aperture 1220 overlaps with the “bottom” edge of the third delivery aperture 1230 along an axis 1403 parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100,1100′

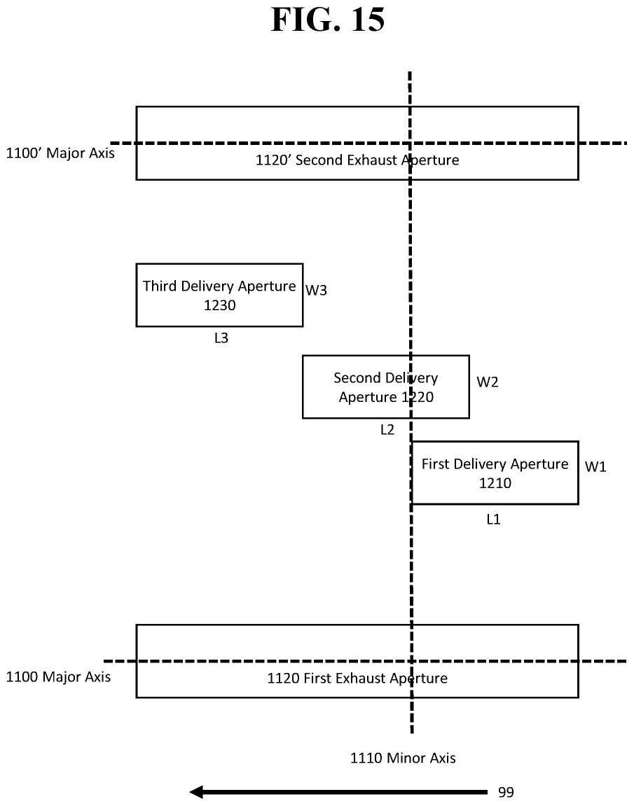

In a fifth example, as shown in FIG. 15, a “top” edge of the third delivery aperture 1230 aligns with the “top” edge of the first exhaust aperture 1120 and second exhaust aperture 1120′ along an axis parallel to the minor axis 1110. Here, the “bottom” edge of the first delivery aperture 1210 align with the “bottom” edge of the first exhaust aperture 1120 and second exhaust aperture 1120′ along an axis parallel to the minor axis 1110. In this example, the “top” edge of the first delivery aperture 1210 overlaps with the “bottom” edge of the second delivery aperture 1220 along an axis parallel to the minor axis 1110. In this example, the “top” edge of the second delivery aperture 1220 aligns with the “bottom” edge of the third delivery aperture 1230 along an axis parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100,1100′

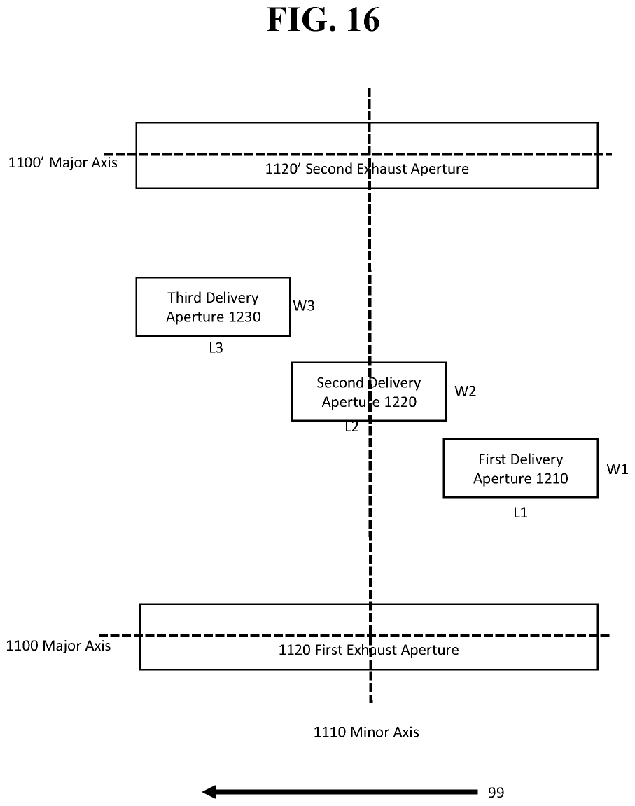

In a sixth example, as shown in FIG. 16, a “top” edge of the third delivery aperture 1230 aligns with the “top” edge of the first exhaust aperture 1120 and second exhaust aperture 1120′ along an axis parallel to the minor axis 1110. Here, the “bottom” edge of the first delivery aperture 1210 align with the “bottom” edge of the first exhaust aperture 1120 and second exhaust aperture 1120′ along an axis parallel to the minor axis 1110. In this example, the “top” edge of the first delivery aperture 1210 aligns with the “bottom” edge of the second delivery aperture 1220 along an axis parallel to the minor axis 1110. In this example, the “top” edge of the second delivery aperture 1220 aligns with the “bottom” edge of the third delivery aperture 1230 along an axis parallel to the minor axis 1110. In this example, the “sides” of the first exhaust aperture 1120, second exhaust aperture 1120′, first delivery aperture 1210, second delivery aperture 1220, and third delivery aperture 1230 are not aligned (i.e., there is spacing) along an axis parallel to the major axis 1100,1100′

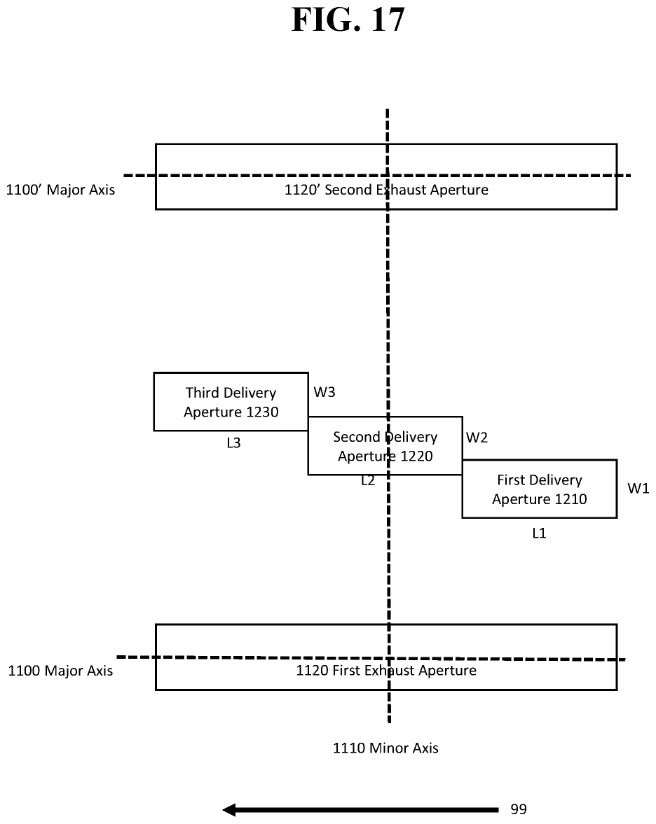

In a seventh example, as shown in FIG. 17, a “top” edge of the third delivery aperture 1230 aligns with the “top” edge of the first exhaust aperture 1120 and second exhaust aperture 1120′ along an axis parallel to the minor axis 1110. Here, the “bottom” edge of the first delivery aperture 1210 align with the “bottom” edge of the first exhaust aperture 1120 and second exhaust aperture 1120′ along an axis parallel to the minor axis 1110. In this example, the “top” edge of the first delivery aperture 1210 aligns with the “bottom” edge of the second delivery aperture 1220 along an axis parallel to the minor axis 1110. In this example, the “top” edge of the second delivery aperture 1220 aligns with the “bottom” edge of the third delivery aperture 1230 along an axis parallel to the minor axis 1110. In this example, the “side” of the first delivery aperture 1210 and first exhaust aperture 1120 are not aligned (i.e., there is spacing) along an axis parallel to the major axis 1100, 1100′. In this example, the “side” of the third delivery aperture 1230 and second exhaust aperture 1120′ are not aligned (i.e., there is spacing) along an axis parallel to the major axis 1100, 1100′. In this example, the “sides” of the first delivery aperture 1210, second delivery aperture 1220, and third delivery aperture 1230 are not aligned (i.e., there is overlap) along an axis parallel to the major axis 1100,1100′

It should be noted that the examples discussed above, in regards to FIGS. 11-17, are not exhaustive and embodiments describe herein may provide for other examples not shown herein.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A method of fabricating a print die, the method comprising:
etching one or more first delivery channels in a first wafer;
etching one or more second delivery channels in a second wafer;
etching one or more exhaust channels into the first wafer;
etching one or more exhaust channels into the second wafer; and
bonding the first wafer to the second wafer, wherein:
exhaust channels in the first wafer align with exhaust channels in the second wafer; and
the one or more first delivery channels in the first wafer do not align with any of the one or more second delivery channels in the second wafer.

2. The method of claim 1, wherein the first and second wafers are Si wafers.

3. The method of claim 1, wherein the one or more first delivery channels consist of a single delivery channel, and the one or more second delivery channels consist of two delivery channels.

4. The method of claim 0, wherein the first and second wafers are arranged such that a region of the second wafer immediately adjacent to the single delivery channel is disposed between the two delivery channels.

5. The method of claim 1, further comprising:
etching one or more exhaust channels in a third wafer;
etching one or more third delivery channels in the third wafer;
bonding the third wafer to the second wafer, wherein:
exhaust channels in the second wafer align with exhaust channels in the third wafer; and
the one or more third delivery channels in the third wafer do not align with any of the one or more second delivery channels in the second wafer

6. The method of claim 0, wherein each first delivery channel is disposed at least 10 μm from each second delivery channel when measured in a line parallel to a major axes of the exhaust channels in the first and second wafers.

7. The method of claim 0, wherein each third delivery channel is disposed at least 20 μm from each second delivery channel when measured in a line parallel to a major axes of the exhaust channels in the first and second wafers.

8. The method of claim 0, wherein the exhaust channels in the first wafer are separated from the exhaust channels in the second wafer by at least 20 μm when measured in a line parallel to a major axes of the exhaust channels in the first and second wafers.

9. The method of claim 0, wherein the exhaust channels in the third wafer are separated from the exhaust channels in the second wafer by at least 20 μm when measured in a line parallel to a major axes of the exhaust channels in the first and second wafers.

10. An organic vapor jet printing (OVJP) deposition device comprising:
a deposition block comprising one or more depositors, each of the one or more depositors comprising, on a surface of the deposition block:
a first exhaust aperture having a major axis and a minor axis smaller than the major axis;
a second exhaust aperture having a major axis and a minor axis smaller than the major axis; and
a plurality of at least three delivery apertures disposed between the first exhaust aperture and the second exhaust aperture and fluidly output-coupled to the first and second exhaust apertures;
wherein the arrangement of the plurality of delivery apertures is not mirror symmetric about any line perpendicular to a first axis of the depositor parallel to the major axis of the first exhaust aperture;
wherein there are no delivery apertures disposed in a first region defined by the outermost edges of the first and second exhaust apertures other than the plurality of delivery apertures; and
wherein there are no exhaust apertures in the first region other than the first and second exhaust apertures.

11. The OVJP deposition device of claim 0, wherein the arrangement of the plurality of delivery apertures is mirror symmetric about the first axis of the depositor.

12. The OVJP deposition device of claim 0, wherein the one or more depositors comprises a plurality of depositors, each having a same arrangement of exhaust and delivery apertures.

13. The OVJP deposition device of claim 0, wherein adjacent depositors share a common exhaust aperture.

14. The OVJP deposition device of claim 0, wherein the plurality of delivery apertures comprises:
a first delivery aperture disposed between the first exhaust aperture and the second exhaust aperture and fluidly output-coupled to the first and second exhaust apertures; and
a second delivery aperture disposed between the first exhaust aperture and the second exhaust aperture and fluidly output-coupled to the first and second exhaust apertures;
wherein the first delivery aperture is separated from the second delivery aperture by at least 5 μm when measured in a direction perpendicular to the major axes of the first and second exhaust apertures; and
wherein the first delivery aperture is separated from the second delivery aperture by at least 0-20 μm when measured in a direction parallel to the major axes of the first and second exhaust apertures.

15. The OVJP device of claim 0, wherein the first delivery aperture is separated from the second delivery aperture by at least 10 μm in the direction perpendicular to the major axes of the first and second exhaust apertures.

16. The OVJP device of claim 0, wherein the first delivery aperture is separated from the second delivery aperture by at least 15 μm in the direction perpendicular to the major axes of the first and second exhaust apertures.

17. The OVJP device of claim 0, wherein the first delivery aperture is separated from the second delivery aperture by at least 20 μm when measured in the direction parallel to the major axes of the first and second exhaust apertures.

18. The OVJP device of claim 0, further comprising:
a third delivery aperture disposed between the first exhaust aperture and the second exhaust aperture and fluidly output-coupled to the first and second exhaust apertures;
wherein the third delivery aperture is separated from the second delivery aperture by at least 15 μm when measured in a direction perpendicular to the major axes of the first and second exhaust apertures; and
wherein the third delivery aperture is separated from the second delivery aperture by at least 0-20 μm when measured in a direction parallel to the major axes of the first and second exhaust apertures.

19. The OVJP device of claim 0, wherein the first exhaust aperture and the second exhaust aperture comprise gaps corresponding to the separation between the first and second delivery apertures and the separation between the second and third delivery apertures.

20. An organic vapor jet printing (OVJP) deposition device comprising:
a deposition block comprising one or more depositors, each of the one or more depositors comprising, on a surface of the deposition block:
a first exhaust aperture having a major axis and a minor axis perpendicular to the major axis;
a second exhaust aperture having a major axis and a minor axis perpendicular to the major axis, wherein the major axis of the second exhaust aperture is parallel to the major axis of the first exhaust aperture; and
three or more delivery apertures disposed between the major axis of the first exhaust aperture and the major axis of the second exhaust aperture and fluidly output-coupled to the first exhaust aperture and second exhaust aperture.

21-42. (canceled)
